(19) United States
(12) Patent Application Publication
(10) Pub. No.: US 2011/0223693 A1
(43) Pub. Date: Sep. 15, 2011

(54) HEAT TREATMENT APPARATUS AND METHOD OF PROCESSING SUBSTRATE

(75) Inventor: Masashi SUGISHITA, Toyama (JP)

(73) Assignee: HITACHI KOKUSAI ELECTRIC INC., Tokyo (JP)

(21) Appl. No.: 13/047,235

(22) Filed: Mar. 14, 2011

(30) Foreign Application Priority Data
Mar. 15, 2010 (JP) 2010-057542
Jan. 17, 2011 (JP) 2011-006732

(51) Int. Cl. H01L 21/66; F27D 11/00

(52) U.S. Cl. 438/5; 219/385; 257/E21.53

(57) ABSTRACT

There are provided a heat treatment apparatus and a method of processing a substrate, which can control uniformity in thickness of a film formed on a substrate. The heat treatment apparatus includes a processing chamber configured to process a substrate; a heating device configured to heat the substrate from a circumferential side of the substrate accommodated in the processing chamber; a cooling gas channel installed between the heating device and the processing chamber; a cooling device configured to flow a cooling gas into the cooling gas channel; a plurality of cooling gas inhalation passages configured to independently communicate with the cooling gas channel in regions into which the heating device is horizontally divided, and installed between the cooling device and the cooling gas channel; first pressure detectors installed respectively in the plurality of cooling gas inhalation passages; and a control unit configured to control the cooling device based on a first pressure value detected by the first pressure detectors.

### CROSS-REFERENCE TO RELATED PATENT APPLICATION

This application claims priority to and the benefit of Japanese Patent Application Nos. 2010-057542 filed on Mar. 15, 2010 and 2011-006732 filed on Jan. 17, 2011, the disclosure of which is incorporated herein by reference.

### FIELD OF THE INVENTION

The present invention relates to a heat treatment apparatus for heat-treating a substrate such as a semiconductor wafer, and a method of processing a substrate.

### DESCRIPTION OF THE RELATED ART

For example, Patent Document 1 discloses a heat treatment apparatus configured to acquire a measurement value of a first thermocouple configured to detect a temperature of a circumferential part of a wafer and a measurement value of a central thermocouple configured to detect a temperature of a central part of the wafer to calculate a deviation between both of the measurement values, compare the deviation between both of the measurement values with a previously stored deviation prior to processing the wafer, correct a pressure value in a reaction tube when the previously stored deviation and the deviation between both of the measurement values are different from each other, and control a heating device and a cooling device based on the corrected pressure value using a control unit in order to process a substrate.

Such a heat treatment apparatus is known to have quenching mechanisms configured to rapidly cool an inside of a furnace. In such quenching mechanisms, a quenching blower exhaust port and a client-facility exhaust are connected to a quenching inhalation port. However, when an inhalation port is installed at a lower portion of the heat treatment apparatus, cooling performance is different in a vertical direction of a reaction furnace. Therefore, use of the quenching mechanism during film formation has an adverse effect on a deviation in film thickness between wafers.

### PRIOR-ART DOCUMENTS

### Patent Documents

Japanese Patent Laid-Open Publication No. 2008-205426

### SUMMARY OF THE INVENTION

An object of the present invention is to provide a heat treatment apparatus and a method of processing a substrate, which can reduce a difference in cooling performance in a vertical direction of a reaction furnace and control uniformity in thickness or quality of a film formed on a substrate.

According to a first feature of the present invention, there is provided a heat treatment apparatus including: a processing chamber configured to process a substrate; a heating device configured to heat the substrate from a circumferential side of the substrate accommodated in the processing chamber; a cooling gas channel installed between the heating device and the processing chamber; a cooling device configured to flow a cooling gas into the cooling gas channel; a plurality of cooling gas inhalation passages installed between the cooling device and the cooling gas channel, each of the plurality of cooling gas inhalation passages communicating with the cooling gas channel in a region defined by horizontally dividing the heating device; a first pressure detector installed in each of the plurality of cooling gas inhalation passages; and a control unit configured to control the cooling device based on a first pressure value detected by the first pressure detector.

Preferably, the heat treatment apparatus further includes a cooling gas exhaust passage configured to communicate with the cooling gas channel at a downstream side of the cooling gas channel, wherein a second pressure detector is installed in the cooling gas exhaust passage, and the control unit controls at least one of the heating device and the cooling device based on a second pressure value detected by the second pressure detector.

Also, preferably, the control unit performs: acquiring a measurement value of a first detection unit configured to detect a state of a peripheral part of the substrate and a measurement value of a second detection unit configured to detect a state of a central part of the substrate; calculating a first deviation between the measurement value of the first detection unit and the measurement value of the second detection unit; comparing the first deviation with a second deviation between a previously stored measurement value of the first detection unit and a previously stored measurement value of the second detection unit; calculating a pressure correction value of a predetermined pressure value in the cooling gas channel based on the first deviation when the second deviation and the first deviation are different from each other; and correcting the predetermined pressure value by means of the pressure correction value.

According to a second feature of the present invention, there is also provided a method of processing a substrate including: heating a substrate from a circumferential side of the substrate accommodated in a processing chamber configured to process the substrate using a heating device; flowing a cooling gas from a plurality of cooling gas inhalation passages to a cooling gas channel installed between the heating device and the processing chamber using a cooling device, each of the plurality of cooling gas inhalation passages communicating with the cooling gas channel in a region defined by horizontally dividing the heating device; detecting a pressure value in the plurality of cooling gas inhalation passages using a pressure detector; and controlling the cooling device by a control unit based on the pressure value detected by the pressure detector.

Preferably, the method of processing a substrate further includes: acquiring by the control unit a measurement value of a first detection unit configured to detect a state of a peripheral part of the substrate and a measurement value of a second detection unit configured to detect a state of a central part of the substrate, calculating a first deviation between the measurement value of the first detection unit and the measurement value of the second detection unit, comparing the first deviation with a second deviation between a previously stored measurement value of the first detection unit and a previously stored measurement value of the second detection unit, calculating a pressure correction value of a predetermined pressure value in the cooling gas channel based on the first deviation when the second deviation and the first deviation are different from each other, and correcting the predetermined pressure value by means of the pressure correction value; and flowing the cooling gas into the cooling gas channel using the cooling device while heating the processing chamber using the heating device, controlling the heating device and the cooling device based on a corrected predetermined pressure value using the control unit, and processing the substrate.

Also, preferably, the method of processing a substrate is used to program a method of maintaining uniform cooling performance and controlling a cooling gas flow rate and process a substrate based on a mounting unit (a mounting device) mounted on a calculator.

### ADVANTAGEOUS EFFECTS

According to the present invention, a heat treatment apparatus and a method of processing a substrate, which can reduce a difference in cooling performance in a vertical direction of a reaction furnace and control uniformity in thickness or quality of a film formed on a substrate, can be provided.

### BRIEF DESCRIPTION OF THE DRAWINGS

FIG. 1 is a diagram schematically illustrating a configuration of a semiconductor manufacturing apparatus according to an embodiment of the present invention.

FIG. 2 is a diagram schematically illustrating a configuration of surroundings of a reaction tube according to an embodiment of the present invention.

FIG. 3 is a diagram schematically illustrating a configuration of a cooling mechanism according to an embodiment of the present invention.

FIG. 4 is a diagram schematically illustrating a configuration of a semiconductor manufacturing apparatus according to an embodiment of the present invention.

FIG. 5 is an explanation diagram illustrating a configuration and a method of correcting a set temperature in the semiconductor manufacturing apparatus according to the embodiment of the present invention using a temperature correction value in a central part of a wafer

FIG. 6 is a chart illustrating data of temperature deviations in the central part acquired in the semiconductor manufacturing apparatus according to the embodiment of the present invention.

FIG. 7 is a first diagram illustrating calculation of a pressure correction amount in the semiconductor manufacturing apparatus according to the embodiment of the present invention.

FIG. 8 is a second diagram illustrating calculation of a pressure correction amount in the semiconductor manufacturing apparatus according to the embodiment of the present invention.

FIG. 9 is a chart illustrating data such as a film thickness of a wafer processed in a semiconductor manufacturing apparatus according to a second embodiment of the present invention.

FIG. 10 is a first diagram illustrating calculation of a pressure correction amount in the semiconductor manufacturing apparatus according to the second embodiment of the present invention.

FIG. 11 is a second diagram illustrating calculation of a pressure correction amount in the semiconductor manufacturing apparatus according to the second embodiment of the present invention.

FIG. 12 is a diagram schematically illustrating a configuration of a cooling mechanism according to a third embodiment of the present invention.

FIG. 13 is a chart illustrating data such as a film thickness of a wafer processed in a semiconductor manufacturing apparatus according to a fourth embodiment of the present invention.

FIG. 14 is a first diagram illustrating calculation of a DEPO processing time correction amount in the semiconductor manufacturing apparatus according to the fourth embodiment of the present invention.

FIG. 15 is a second diagram illustrating calculation of a DEPO processing time correction amount in the semiconductor manufacturing apparatus according to the fourth embodiment of the present invention.

FIG. 16 is a diagram schematically illustrating a configuration of a semiconductor manufacturing apparatus according to a fifth embodiment of the present invention.

### DETAILED DESCRIPTION OF THE PREFERRED EMBODIMENTS

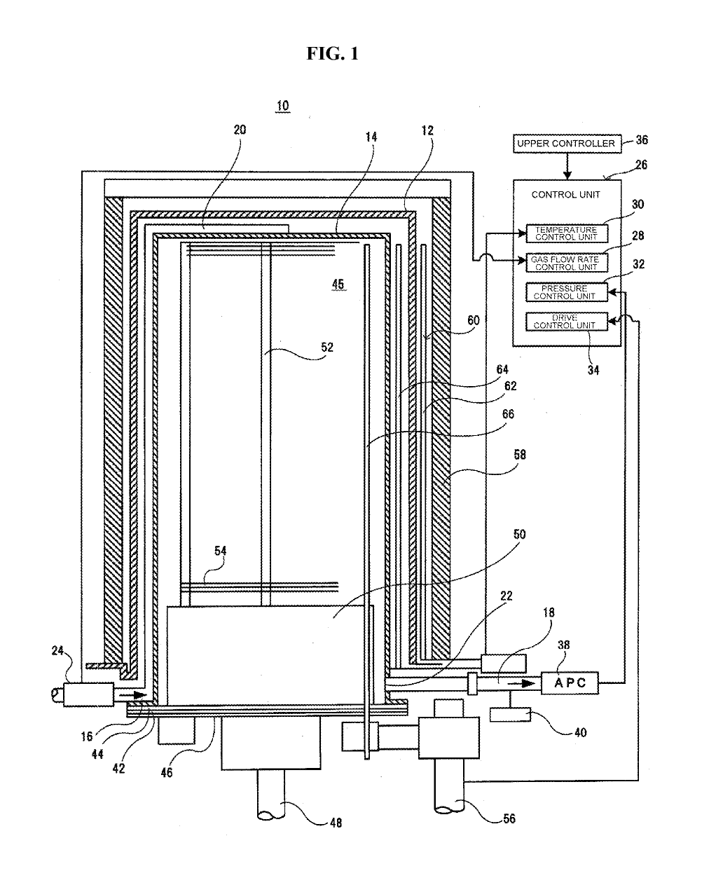

FIG. 1 schematically illustrates a configuration of a semiconductor manufacturing apparatus 10 which is one example of a heat treatment apparatus according to an embodiment of the present invention.

The semiconductor manufacturing apparatus 10 includes a uniform heat tube 12. The uniform heat tube 12 is, for example, made of a heat-resistant material such as SiC, and has a cylindrical shape with its upper end closed and its lower end open. A reaction tube 14 used as a reaction container is installed inside the uniform heat tube 12. The reaction tube 14 is, for example, made of a heat-resistant material such as quartz (SiO₂), has a cylindrical shape with its lower end open, and is concentrically disposed in the uniform heat tube 12.

In a lower portion of the reaction tube 14, an exhaust tube 18 is, for example, connected to a gas supply tube 16 made of SiO₂. An introduction member 20 having an introduction port formed therein to introduce a gas into the reaction tube is installed at the gas supply tube 16. The gas supply tube 16 and the introduction member 20 are installed, for example, in a fine tubular shape along a side portion of the reaction tube 14 from a lower portion of the reaction tube 14, and span from a ceiling part of the reaction tube 14 to an inside of the reaction tube 14. Also, the exhaust tube 18 is connected to an exhaust port 22 formed in the reaction tube 14.

The gas supply tube 16 flows a gas from the ceiling part of the reaction tube 14 into the inside of the reaction tube 14, and the exhaust tube 18 connected to the lower portion of the reaction tube 14 is used to exhaust a gas from the lower portion of the reaction tube 14. A processing gas used in the reaction tube 14 is supplied into the reaction tube 14 via the introduction member 20 and the gas supply tube 16. Also, a mass flow controller (MFC) 24 used as a flow rate control means configured to control a flow rate of a gas, and a water vapor generator (not shown) are connected to the gas supply tube 16. The MFC 24 is connected to a gas flow rate control unit (a gas flow rate control device) 28 provided with a control unit (a control device) 26. Flow rates of gas and vapor (H₂O) to be supplied are, for example, controlled to a predetermined preset amount by means of the gas flow rate control unit 28.

In addition to the above-described gas flow rate control unit 28, the control unit 26 includes a temperature control unit (a temperature control device) 30, a pressure control unit (a pressure control device) 32 and a drive control unit (a drive control device) 34. Also, the control unit 26 is connected to an upper controller 36, and is controlled by the upper controller 36.

An automatic pressure controller (APC) 38 used as a pressure regulator and a pressure sensor 40 used as a pressure detection means are installed at the exhaust tube 18. The APC 38 controls an amount of a gas flowing out of the reaction tube 14, based on a pressure detected by the pressure sensor 40, and controls the reaction tube 14 so that an inside of the reaction tube 14 can be, for example, maintained at a uniform pressure.

Also, a base 42, which is, for example, made of SiO₂, has a disk-like shape and is used as a holding body, is installed via an O-ring 44 at an opening formed at a lower end of the reaction tube 14. The base 42 may be attached/detached to/from the reaction tube 14, and hermetically seal the reaction tube 14 in a state where the base 42 is mounted on the reaction tube 14. The base 42 is, for example, installed at a suitable surface facing upwards against a gravity direction of a seal cap 46 formed in a substantially disk-like shape. That is, a processing chamber 45 is formed as the base 42 is installed via the O-ring 44 at the opening formed at the lower end of the reaction tube 14.

A rotating shaft 48 used as a rotating means is connected to the seal cap 46. The rotating shaft 48 is rotated by receiving a driving force from a drive source (not shown), and then rotates a quartz cap 50 used as a holding body, a boat 52 used as a substrate holding member and a wafer 54 held by the boat 52 and corresponding to a substrate. A rotating speed of the rotating shaft 48 is controlled by the above-described control unit 26.

Also, the semiconductor manufacturing apparatus 10 includes a boat elevator 56 used to move the boat 52 in a vertical direction, and is controlled by the above-described control unit 26.

A heater 58 used as a heating device (a heating means) is concentrically disposed in a circumference of the reaction tube 14. The heater 58 is controlled by the temperature control unit 30, based on a temperature detected by a temperature detection unit (a temperature detection device) 60 including a first thermocouple 62, a second thermocouple 64 and a third thermocouple 66, so that a temperature in the reaction tube 14 can reach a processing temperature set in the upper controller 36.

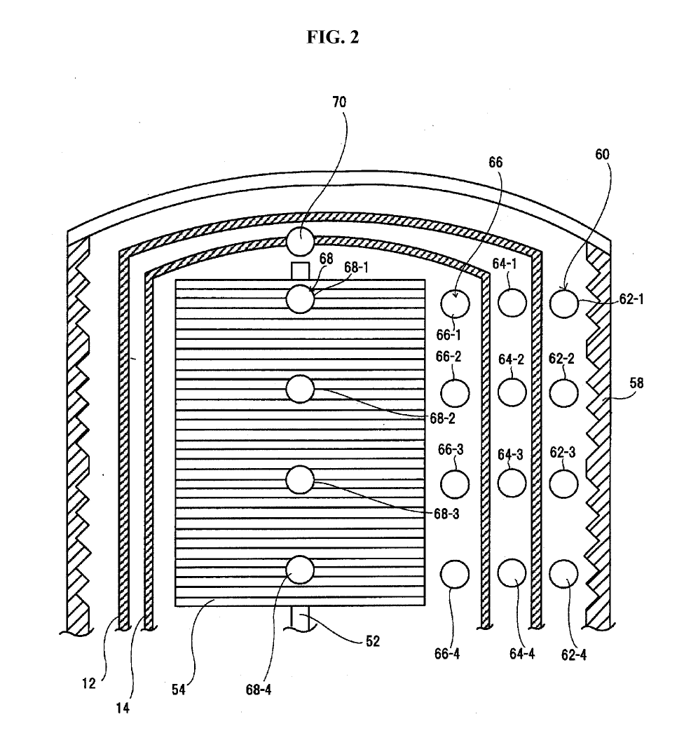

FIG. 2 schematically illustrates a configuration of surroundings of the reaction tube 14. The semiconductor manufacturing apparatus 10 includes the temperature detection unit 60, as described above. The temperature detection unit 60 includes a first thermocouple 62, a second thermocouple 64 and a third thermocouple 66. In addition to these thermocouples, the temperature detection unit 60 includes a central thermocouple 68 configured to detect a temperature in a substantially central part of the wafer 54 and a ceiling thermocouple 70 configured to detect a temperature around a ceiling part of the boat 52, as shown in FIG. 2. Also, since the central thermocouple 68 may function as a substitute for the third thermocouple 66, the third thermocouple 66 may not be provided.

The first thermocouple 62 is used to detect a temperature of the heater 58. The second thermocouple 64 is used to detect a temperature between the uniform heat tube 12 and the reaction tube 14. Here, the second thermocouple 64 may be installed between the reaction tube 14 and the boat 52 to detect a temperature in the reaction tube 14. The third thermocouple 66 is installed between the reaction tube 14 and the boat 52. The third thermocouple 66 is installed closer to the boat 52 than the second thermocouple 64, thereby detecting a temperature in a position closer to the boat 52. Also, the third thermocouple 66 is used to measure uniformity of the temperature in the reaction tube 14 of a temperature stability period.

In the semiconductor manufacturing apparatus 10 configured as described above, one case of an operation in which oxidation and diffusion of the wafer 54 are performed in the inside (the processing chamber 45) of the reaction tube 14 will be described (see FIG. 1).

First, the boat 52 is lowered by the boat elevator 56. Next, a plurality of wafers 54 are held by the boat 52. Then, the plurality of wafers 54 are heated by the heater 58, and a temperature of the processing chamber 45 is set to a predetermined preset processing temperature.

Next, the inside (the processing chamber 45) of the reaction tube 14 is filled in advance with an inert gas under the control of the MFC 24 connected to the gas supply tube 16. The boat 52 is raised by the boat elevator 56, and transferred into the reaction tube 14. In this case, an inner temperature of the reaction tube 14 is maintained at a predetermined processing temperature. A pressure in the reaction tube 14 is maintained at a predetermined pressure, and the boat 52 and the wafer 54 held by the boat 52 are then rotated by the rotating shaft 48. At the same time, a processing gas is supplied from the gas supply tube 16, or a vapor is supplied to a water vapor generator (not shown). The supplied gas is uniformly supplied to the wafer 54 as the reaction tube 14 is lowered.

During the oxidation/diffusion process, the supplied gas is exhausted from the processing chamber 45 via the exhaust tube 18, the processing chamber 45 is controlled by the APC 38 so that a pressure in the processing chamber 45 can reach a predetermined pressure, and the oxidation/diffusion of the wafer 54 are performed for a predetermined time. When the oxidation/diffusion is completed, the oxidation/diffusion of the wafer 54 next to the wafer 54 that has been continuously processed should be performed. Therefore, a gas in the reaction tube 14 is replaced with an inert gas, and a pressure in the reaction tube 14 is adjusted to a normal pressure. Then, the boat 52 is lowered by the boat elevator 56, and the boat 52 and the processed wafer 54 are extracted from the reaction tube 14.

The processed wafer 54 on the boat 52 extracted from the reaction tube 14 is exchanged with an unprocessed wafer 54, and the unprocessed wafer 54 is raised in the reaction tube 14 and undergoes the oxidation/diffusion process.

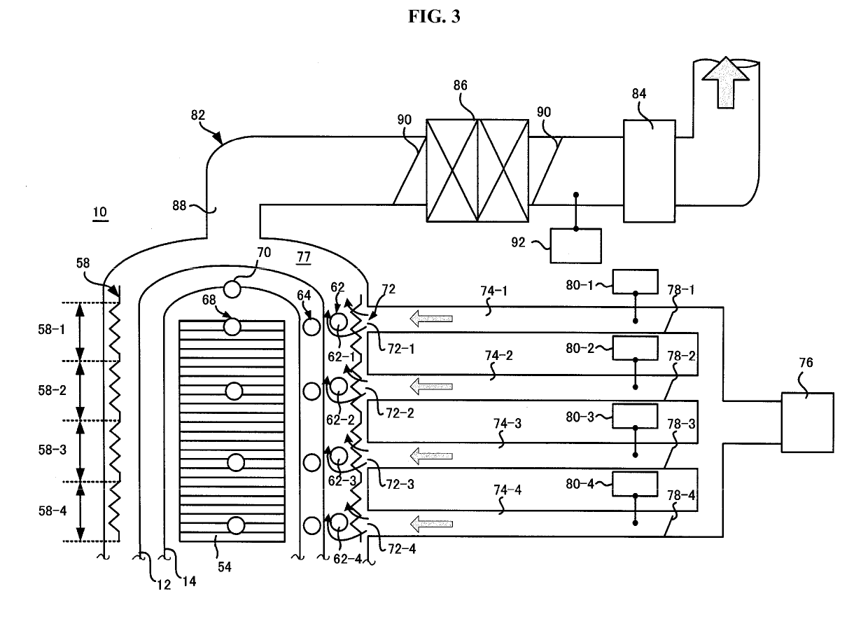

FIG. 3 schematically illustrates a configuration of a cooling mechanism in addition to the configurations shown in FIGS. 1 and 2.

As shown in FIG. 3, in the semiconductor manufacturing apparatus 10 according to the embodiment of the present invention, a cooling mechanism configured to cool an inside of the reaction tube 14 is installed at a circumference of the heater 58 serving as a heating device. Here, a region in which the heater 58 is disposed is horizontally divided from an upper portion to a lower portion thereof. More specifically, the region in which the heater 58 is disposed is set to correspond to heaters 58-1, 58-2, 58-3 and 58-4 in order from an upper portion thereof. A first thermocouple 62-1, a second thermocouple 64-1 and a central thermocouple 68-1 are disposed in a region of the heater 58-1. Also, a first thermocouple 62-2, a second thermocouple 64-2 and a central thermocouple 68-2 are disposed in a region of the heater 58-2. Also, a first thermocouple 62-3, a second thermocouple 64-3 and a central thermocouple 68-3 are disposed in a region of the heater 58-3. Furthermore, a first thermocouple 62-4, a second thermocouple 64-4 and a central thermocouple 68-4 are disposed in a region of the heater 58-4.

Also, an inhalation port 72 configured to inhale a cooling gas is provided to correspond to the divided regions of the heater 58. More specifically, an inhalation port 72-1 is installed in the region of the heater 58-1, an inhalation port 72-2 is installed in the region of the heater 58-2, an inhalation port 72-3 is installed in the region of the heater 58-3, and an inhalation port 72-4 is installed in the region of the heater 58-4.

The inhalation ports 72-1 through 72-4 are connected respectively to inhalation tubes 74-1 through 74-4, and the inhalation tubes 74-1 through 74-4 are connected to a cooling gas inhalation device 76 configured to inhale a cooling gas. Also, control valves 78-1 through 78-4 configured to control a pressure value in each of the inhalation tubes 74-1 through 74-4 through adjustment of an opening angle of a pressure value are installed at the cooling gas inhalation device 76 connected to the inhalation tubes 74-1 through 74-4. Also, pressure sensors 80-1 through 80-4 used as detection units (detection devices) to detect a pressure in each of the inhalation tubes 74-1 through 74-4 are installed between the inhalation ports 72-1 through 72-4 and the control valves 78-1 through 78-4. Here, the pressure sensor 80 has been installed between the inhalation port 72 and the control valve 78, but installation of the pressure sensor 80 in a closer vicinity of the inhalation port 72 is preferred.

An exhaust unit 82 is installed at an upper portion of the reaction tube 14, and the exhaust unit 82 includes a cooling gas exhaust device 84, for example, made of a blower and a radiator 86. The cooling gas exhaust device 84 is mounted in a front end side of an exhaust tube 88 constituting the exhaust unit 82. The radiator 86 is mounted in a position between a proximal portion of the exhaust tube 88 and the cooling gas exhaust device 84. Also, shutters 90 and 90 are installed respectively at an upstream side and a downstream side of the radiator 86 of the exhaust tube 88 in a direction where a cooling gas flows. The shutters 90 and 90 are opened and closed under the control of a shutter control unit (a shutter control device) (not shown). Also, a pressure sensor 92 used as a detection unit (a detection device) to detect a pressure in the exhaust tube 88 is installed in a position between the radiator 86 of the exhaust tube 88 and the cooling gas exhaust device 84. Here, in the case of the position in which the pressure sensor 92 is installed, the pressure sensor 92 is preferably installed in a position located as close as the radiator 86 in the exhaust tube 88 configured to connect the cooling gas exhaust device 84 to the radiator 86.

A cooling gas channel 77 is formed between the heater 58 and the uniform heat tube 12 so that a cooling gas can pass through the cooling gas channel 77. The cooling gas supplied from the cooling gas inhalation device 76 is supplied from the inhalation ports 72-1 through 72-4 into the heater 58 via the inhalation tubes 74-1 through 74-4. The cooling gas flows up the uniform heat tube 12. For example, the cooling gas includes air, nitrogen (N₂), etc. Also, the cooling gas channel 77 is configured to discharge the cooling gas from spaces between the first thermocouples 62-1 through 62-4 toward the uniform heat tube 12.

The cooling gas cools the uniform heat tube 12, and the cooled uniform heat tube 12 cools the wafer 54, which is set at the boat 14 in the reaction tube 52, from a main direction (a circumferential side) thereof. That is, the wafers 54 set at the uniform heat tube 12, the reaction tube 14 and the boat 52 are cooled from a main direction (a circumferential side) thereof by means of the cooling gas passing through the cooling gas channel 77. The cooling gas passing through the cooling gas channel 77 is exhausted out of an apparatus via the exhaust unit 82 used as a cooling gas exhaust passage.

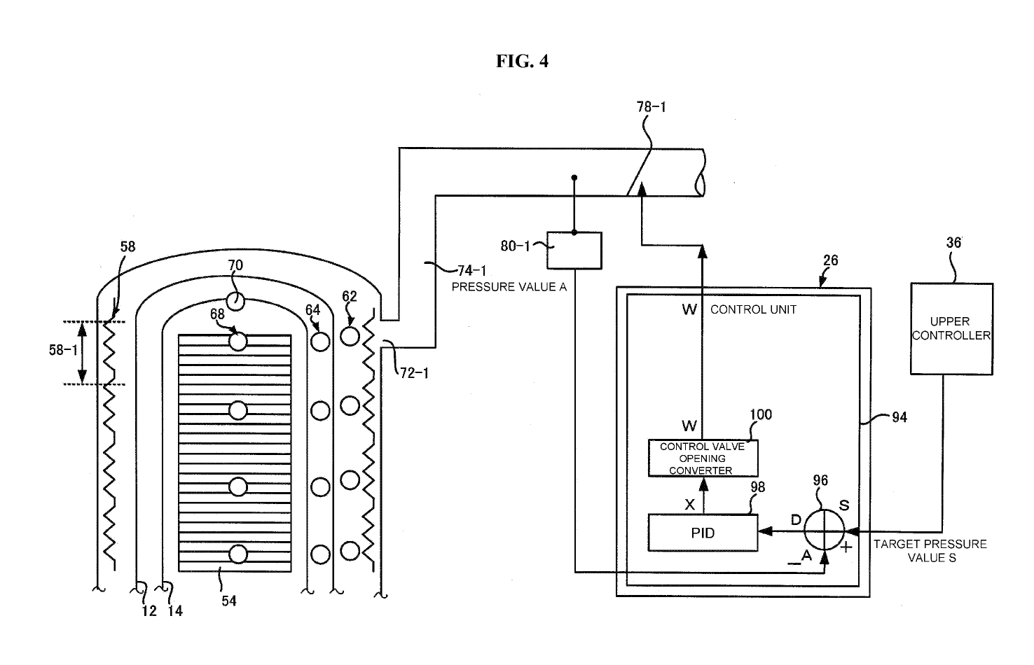

As described above, the control unit (a control device) 26 includes the gas flow rate control unit (a gas flow rate control device) 28, the temperature control unit (a temperature control device) 30, the pressure control unit (a pressure control device) 32 and the drive control unit (a drive control device) 34 (see FIG. 1), and also includes a cooling gas flow rate control unit (a cooling gas control device) 94, as shown in FIG. 4.

FIG. 4 is a diagram exemplifying a region of the heater 58-1 in a configuration of a cooling mechanism according to an embodiment of the present invention. The cooling gas flow rate control unit 94 configured to control a flow rate of a cooling gas includes a subtractor 96, a PID operator 98, and a control valve opening converter 100.

A target pressure value S is input from the upper controller 36 into the subtractor 96. Also, in addition to the target pressure value S, a pressure value A measured by the pressure sensor 80-1 is input into the subtractor 96. A deviation D acquired by subtracting the pressure value A from the target pressure value S is output from the subtractor 96.

The deviation D is input into the PID operator 98. A PID operation is performed at the PID operator 98, based on the input deviation D, and an operating amount X is calculated. The calculated operating amount X is input into the control valve opening converter 100, and converted into an opening angle W of a control valve. Then, the converted opening angle W is output. An opening angle of a control valve is changed by the output opening angle W of the control valve 78-1. The pressure value A from the pressure sensor 80-1 is input into the subtractor 96 at all times or in predetermined time intervals, and the opening angle W of the control valve 78-1 of the cooling gas inhalation device 76 continues to be controlled, based on the pressure value A, so that the deviation D between the target pressure value S and the pressure value A can reach 0.

That is, as the control valve 78-1 is controlled so that the deviation between the pressure value A measured by the pressure sensor 80-1 and the previously set target pressure value S can reach 0, a pressure of the inhalation port 72-1 is controlled to a certain constant pressure value.

Also, although the region of the heater 58-1 has been illustrated as one example, opening angles of the control valves 78-2 through 78-4 are also controlled in the regions of the heaters 58-2 through 58-4, respectively.

As described above, in the semiconductor manufacturing apparatus 10, by using the cooling gas inhalation device 76, air used as a cooling medium is allowed to flow between an inner side of the heater 58 and the reaction tube 14, the reaction tube 14 and a wire constituting the heater 58 are cooled, and a temperature in each of the regions in which the reaction tube 14 is divided in a vertical direction is controlled. Therefore, temperature controllability of the wafer 54 held in the reaction tube 14 is good.

That is, transferred heat includes heat transferred by radiation and heat transferred by propagation, only the heat transferred by radiation is transferred to the wafer 54 in the semiconductor manufacturing apparatus 10, which contributes to an increase in temperature of the wafer 54, and the heat transferred by propagation is mainly cooled by air flowing between the inner side of the heater 58 and the reaction tube 14, and emitted. Therefore, in order to supplement an amount of the heat emitted by cooling of the air around the wire of the heater 58, an output of the heater 58 is increased. Then, a temperature of the wire of the heater 58 is further increased by the increase in output of the heater 58, and radiant heat is also increased. Here, the heat transferred by radiation has a much more rapid propagation speed than the heat transferred by propagation. Therefore, the semiconductor manufacturing apparatus 10 in which wafers in the reaction tube 14 are heated by the radiant heat has good temperature controllability.

Also, a temperature of the reaction tube 14 is also lowered by cooling by the air. Then, when the temperature of the reaction tube 14 is lowered, heat transfer from an edge part of the wafer 54 to the reaction tube 14 is performed. As a result, a temperature distribution of the wafer 54 is lowered more in the edge part than in the central part, and can be changed from a predetermined concave temperature distribution in which a temperature of the edge part is higher than a temperature of the central part to a predetermined convex temperature distribution in which the temperature of the edge part is lower than the temperature of the central part.

When the temperature distribution of the wafer 54 is uniform, a film thickness of a thin film formed in the wafer 54 is distributed in a concave shape in which a film thickness of the edge part is thicker than that of the central part. Therefore, when the temperature distribution of the wafer 54 is formed in a convex shape by controlling the temperature as described above, the uniformity in film thickness of the wafer 54 may be improved.

Also, in the semiconductor manufacturing apparatus 10, a front end side of the exhaust tube 88 is connected to an exhaust facility such as a factory in which the semiconductor manufacturing apparatus 10 is installed, as described above, and the cooling gas is exhausted from the reaction tube 14 via the exhaust tube 88. Therefore, a cooling effect by the cooling gas exhaust device 84 may be highly varied by an exhaust pressure of the exhaust facility such as the factory. Then, when the cooling effect by the cooling gas exhaust device 84 is varied, a temperature distribution in a surface of the wafer 54 is affected. Therefore, a frequency of the cooling gas exhaust device 84 is controlled so that the exhaust pressure from the exhaust tube 88 can be constantly maintained.

Also, in the semiconductor manufacturing apparatus 10, for example, when a maintenance task such as exchange of the thermocouple such as the first thermocouple 62 is performed, an error in position where the first thermocouple 62 is installed may be caused, and thus a film thickness of a thin film formed on the wafer 54 processed before the maintenance task may be different from that of a thin film formed on the wafer 54 processed after the maintenance task. When the plurality of semiconductor manufacturing apparatuses 10 having the same specification are provided, thin films formed in the respective semiconductor manufacturing apparatus 10 may also be different in film thickness.

Thus, there is much more research being conducted to improve uniformity of thin films formed in the semiconductor manufacturing apparatus 10 according to the present invention, for example, thin films formed between the plurality of semiconductor manufacturing apparatuses 10 having the same specification.

That is, in the semiconductor manufacturing apparatus 10, a temperature of the central part of the wafer 54, which is a temperature value from the central thermocouple 68, and a temperature of the ceiling part of the boat 52, which is a temperature value from the ceiling thermocouple 70 are acquired when a temperature of the wafer 54 reaches a previously set temperature based on the output from the second thermocouple 64, and a correction value for a predetermined pressure value (a difference in pressure from an atmosphere) is calculated from this acquired data, for example, after the maintenance task. Hereinafter, the region of the heater 58-1 will be illustrated as one example in further detail.

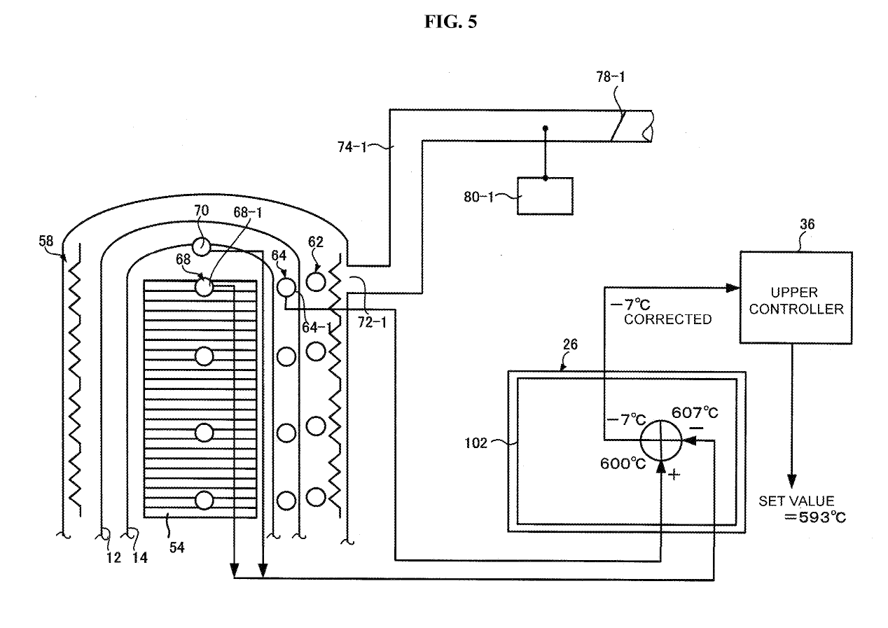

FIG. 5 is an explanation diagram illustrating a configuration and a method of correcting a set temperature at the region of the heater 58-1 using a temperature correction value of the central part of the wafer 54. The above-described control unit 26 includes a wafer central part temperature correction/operation unit 102 (a wafer central part temperature correction/operation device).

Here, a case where the second thermocouple 64-1 is set to 600° C. will be described. The wafer central part temperature correction/operation unit 102 acquires an output value (a temperature in a central part of a wafer) of the central thermocouple 68-1 and an output value (a temperature in a ceiling part of a wafer) of the ceiling thermocouple 70 when controlled by the second thermocouple 64-1, and stores deviations between each of the acquired output values and an output value (an inner temperature) of the second thermocouple 64-1.

In this case, the output values are stored by the following equations:

Inner Temperature−Wafer Central Part Temperature=Wafer Central Part Temperature Deviation

or,

Inner Temperature−Wafer Ceiling Part Temperature=Wafer Ceiling Part Temperature Deviation

Also, the predetermined pressure value in this case is also stored. The data is acquired under a plurality of conditions by maintaining the constant set temperature and changing the predetermined pressure value.

For example, it is assumed that a set temperature is set to 600° C., an inner temperature is set to 600° C., and a wafer central part temperature is set to 607° C. In this case, when the inner temperature is assumed to be a temperature in an edge part of the wafer 54, the set temperature is 600° C., and the wafer central part temperature is 607° C., which is different from the set temperature. Thus, the wafer central part temperature deviation acquired from the following equation is output to the upper controller 36, and corrected for the set value.

Temperature Deviation in Central Part of Wafer=600° C.-607° C.=−7° C.

Therefore, the central part of the wafer 54 may be changed to 600° C. using the upper controller 36.

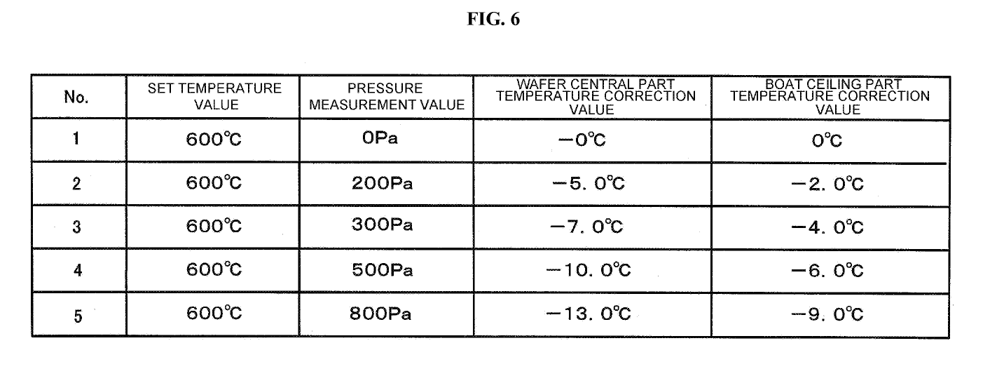

FIG. 6 illustrates one example of a plurality of acquired data sets.

Next, the calculation of the pressure correction value will be described.

For example, when it is assumed that a current boat ceiling part temperature deviation is referred to as “t1,” a current predetermined pressure value is referred to as “p1,” a boat ceiling part temperature correction value corresponding to p1 is referred to as “b1,” a pressure measurement value of a plus side in the acquired data is referred to as “pp,” a boat ceiling part temperature correction value in a plus side is referred to as “tp,” a minus-side pressure measurement value in the acquired data is referred to as “pm,” and a minus-side boat ceiling part temperature correction value is referred to as “tm,” a pressure correction amount px is calculated from the following Equations 11 and 12, depending on sizes of t1 and b1.

That is, the pressure correction amount px is calculated as follows:

If t1<b1,

px=(b1−t1)*{(p1−pm)/(b1−tm)} (Equation 11)

If t1>b1,

px=(b1−t1)*{(pp−p1)/(tp−b1)} (Equation 12).

Hereinafter, the cases in which t1<b1 and t1>b1 will be described in further detail as one example.

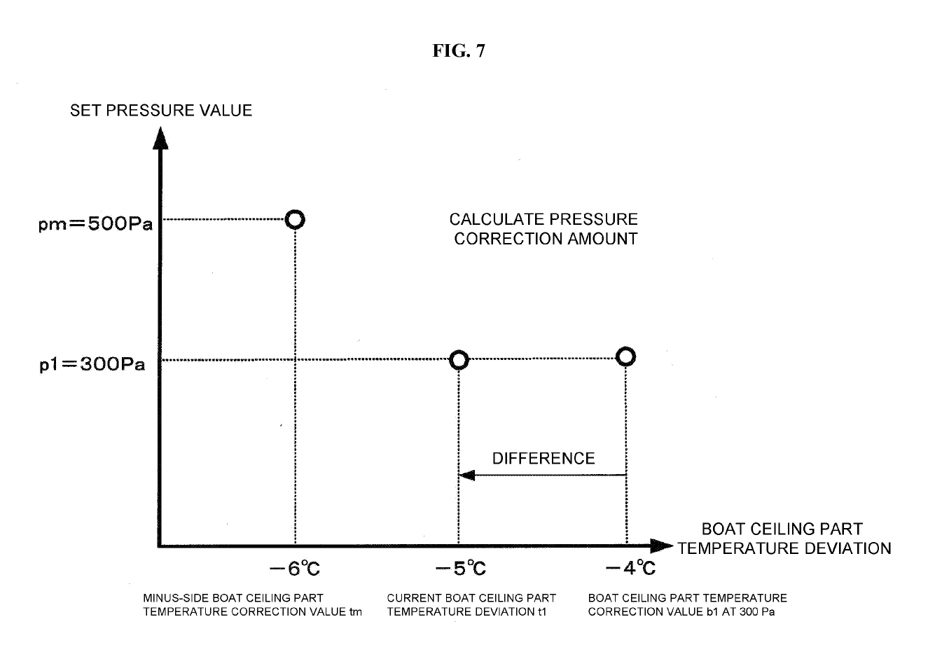

FIG. 7 is an explanation diagram illustrating calculation of the pressure correction amount px when t1<b1.

First, a temperature deviation between a previously acquired boat ceiling part temperature deviation b1 and a current boat ceiling part temperature deviation t1 is calculated as b1−t1

Next, a pressure correction amount for a boat ceiling part temperature deviation of +1° C. is calculated from the previously acquired data as (p1−pm)/(b1−tm) from relationships of “a current predetermined pressure value p1 and a boat ceiling part temperature deviation b1 corresponding to p1” and “a minus-side pressure value pm and a boat ceiling part temperature deviation tm corresponding to pm.”

In one example shown in FIG. 7, a boat ceiling part temperature correction value corresponding to 300 Pa is −4° C., and −6° C. is extracted as the minus side thereof as shown in No. 4 of FIG. 6.

Also, from the previously acquired data, the predetermined pressure value p1 becomes 300 Pa, and the boat ceiling part temperature deviation b1 becomes −4° C.

Also, when the predetermined pressure value pm is 500 Pa, the pressure correction amount acquired from the following equation is required in order to change the boat ceiling part temperature deviation tm by +2° C. from −6° C. to −4° C.:

300 Pa(p1)−500 Pa(pm)=−200 Pa.

A case where a current pressure measurement value is set to 300 Pa and a current boat ceiling part temperature deviation acquired from the measurement results is set to −5° C. will be illustrated as one example.

In this case, first, a boat ceiling part temperature correction value corresponding to a currently used predetermined pressure value is used as a search key, the closest boat ceiling part correction value from the search key is selected from the plus and minus sides of the plurality of acquired data shown in FIG. 6, and calculation is performed using the selected data.

Thus, the pressure correction amount is calculated as follows:

Pressure correction value per +1° C.=−200 Pa/+2° C.=−100 Pa/° C.

That is, since the difference (b1−t1) is corrected per +1° C., the pressure correction amount is calculated as follows:

+1° C.*(−100 Pa/° C.)=−100 Pa.

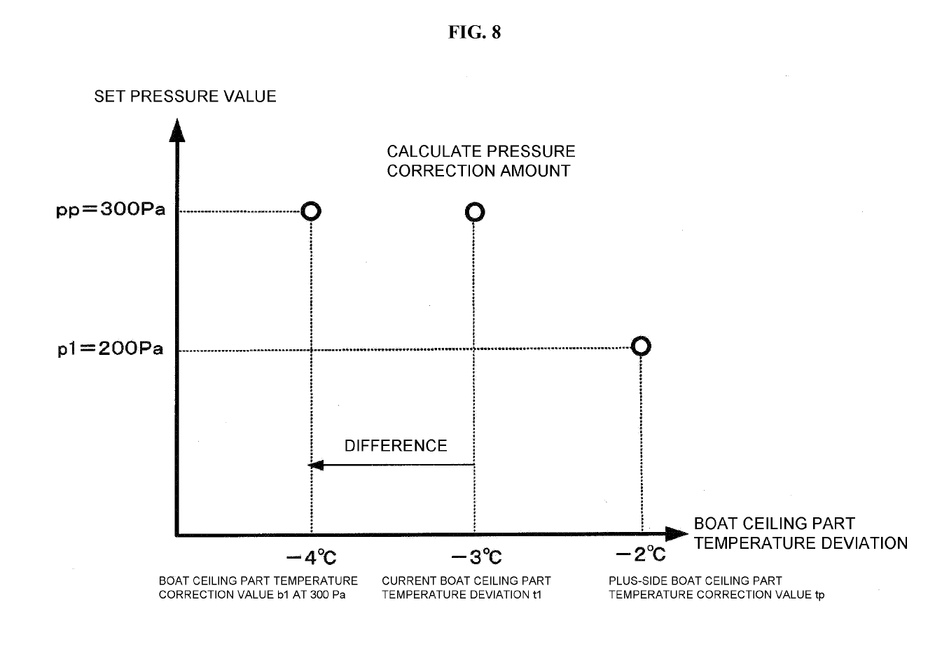

FIG. 8 is an explanation diagram illustrating calculation of the pressure correction amount px when t1>b1.

First, a temperature deviation between a previously acquired boat ceiling part temperature deviation b1 and a current boat ceiling part temperature deviation t1 is calculated.

Next, a pressure correction amount for a boat ceiling part temperature deviation of −1° C. is calculated from the previously acquired data as (pp−p1)/(tp−b1) from relationships of “a current predetermined pressure value p1 and a boat ceiling part temperature deviation b1 corresponding to p1” and “a plus-side pressure value pp in the acquired data and a boat ceiling part temperature deviation tp corresponding to pp.”

Here, when a current pressure measurement value is set to 300 Pa and a current boat ceiling part temperature deviation obtained from the measurement results is set to −3° C., the predetermined pressure value pp becomes 300 Pa and the boat ceiling part temperature deviation b1 becomes −4° C. according to the previously acquired data shown in FIG. 6. Also, the predetermined pressure value p1 becomes 200 Pa, and the boat ceiling part temperature deviation tp becomes −2° C.

Therefore, the pressure correction amount acquired from the following equation is required to change a temperature by −2° C. from the boat ceiling part temperature deviation tp of −2° C. to the boat ceiling part temperature deviation b1 of −4° C. from the previously acquired data:

300 Pa(p1)−200 Pa(pp)=+100 Pa.

That is, the boat ceiling part temperature correction value corresponding to 300 Pa is −4° C., and −2° C. is detected as the plus side thereof as shown in No. 2 of FIG. 6.

Thus, the pressure correction amount is calculated as follows:

Pressure Correction Amount per +1° C.=−100 Pa/2° C.=−50 Pa/° C.

In this example, since the correction is performed by (b1−t1)=−1° C., the pressure correction amount is calculated as follows:

−1° C.*(−50 Pa/° C.)=+50 Pa.

The pressure correction amount px when one of the boat ceiling part temperature deviation t1 and the boat ceiling part temperature correction value b1 is higher than the other has been explained above, but the correction is unnecessary when t1 and b1 are equal to each other.

Furthermore, in the above-described calculation of the pressure correction value, the reason for calculating the pressure correction amount for an increase of the boat ceiling part temperature deviation by 1° C. using the relationships of a detected plus-side or minus-side pressure value and a boat ceiling part temperature deviation corresponding to the detected plus-side or minus-side pressure value, and a current predetermined pressure value p1 and a boat ceiling part temperature deviation b1 corresponding to the current predetermined pressure value p1 is that the pressure correction amount is considered to vary according to the boat ceiling part temperature.

For example, the pressure correction amount used to change the boat ceiling part temperature correction value by +2° C. from −6° C. to −4° C. is not necessarily equal to the pressure correction amount used to change the boat ceiling part temperature correction value by +2° C. from −4° C. to −2° C. due to variations in radiant heat from the wire of the heater 58, heat transfer from the edge part of the wafer 54 to the reaction tube 14, and heat transfer between the central part and the edge part of the wafer 54.

Therefore, in the semiconductor manufacturing apparatus 10 according to this embodiment, in order to calculate a pressure correction amount using variations of temperature correction values in a closer boat ceiling part, the pressure correction amount is calculated using a minus-side boat ceiling part temperature deviation and a predetermined pressure value when a current boat ceiling part temperature deviation is smaller than a boat ceiling part temperature deviation corresponding to a current predetermined pressure value, and the pressure correction amount is calculated using a plus-side boat ceiling part temperature deviation and a predetermined pressure value when a current boat ceiling part temperature deviation is greater than a boat ceiling part temperature deviation corresponding to a current predetermined pressure value.

Next, a second embodiment of the present invention will be described.

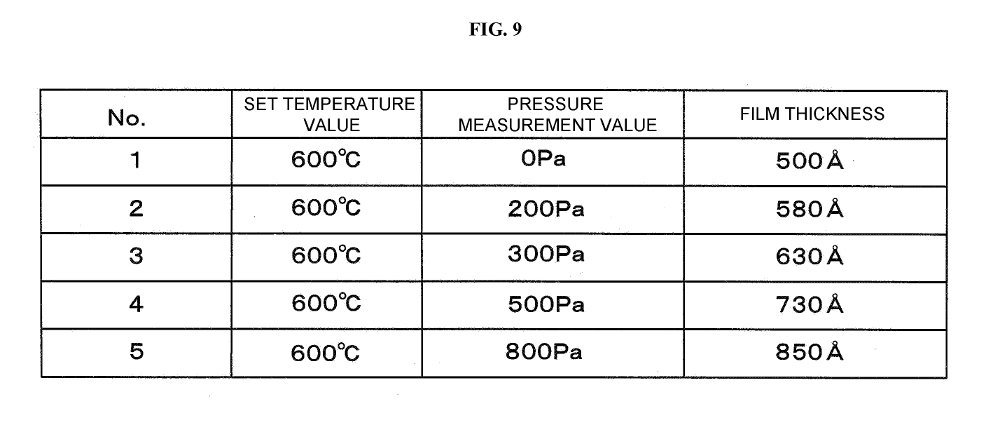

In the above-described embodiment, the pressure correction amount px is calculated using the temperature correction value of the boat ceiling part, whereas in the other embodiments, the pressure correction amount px is calculated using a film thickness of the wafer 54 on which a thin film is formed in advance. Hereinafter, the other embodiments will be described in detail. In the description, data such as a measured film thickness is used for the wafer 54 on which a thin film is formed in advance under certain conditions as shown in FIG. 9.

When a current film thickness of the wafer 54 is referred to as “a1,” a current predetermined pressure value is referred to as “p1,” a film thickness corresponding to the current predetermined pressure value p1 is referred to as “c1,” a searched plus-side pressure measurement value is referred to as “pp,” a plus-side film thickness in a plurality of previously acquired data is referred to as “pc,” a minus-side pressure measurement value in a plurality of previously acquired data is referred to as “pm,” and a minus-side film thickness is referred to as “tc,” a pressure correction amount px is calculated from the following Equations 21 and 22, depending on sizes of the current film thickness a1 and the film thickness c1 corresponding to the current predetermined pressure value p1.

That is, the pressure correction amount px is calculated as follows:

If a1<c1,

px=(c1−a1)*{(p1−pm)/(c1−tc)} (Equation 21)

If a1>c1,

px=(c1−a1)*{(pp−p1)/(pc−c1)} (Equation 22).

Hereinafter, the cases in which a1<c1 and a1>c1 will be described in further detail as one example.

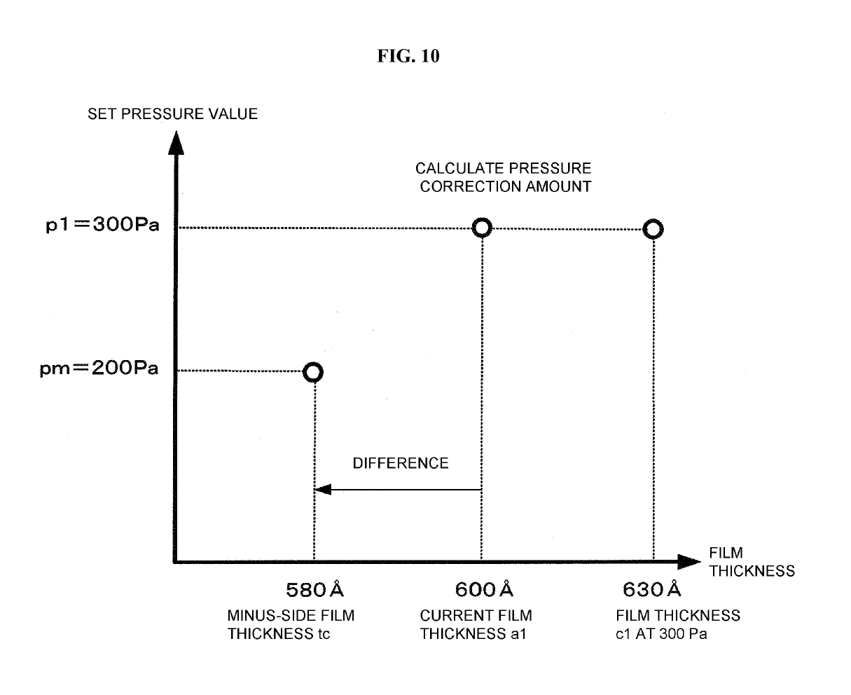

FIG. 10 is an explanation diagram illustrating calculation of the pressure correction amount px when a1<c1.

First, a difference between a previously acquired film thickness c1 and a current film thickness a1 is calculated as c1-a1.

Next, a pressure correction amount for a film thickness of −1 Å is calculated from the previously acquired data as (p1−pm)/(c1−tc) from relationships of “a current predetermined pressure value p1 and a film thickness c1 corresponding to p1” and “a detected minus-side pressure value pm and a film thickness tc corresponding to pm.” That is, the film thickness corresponding to the pressure measurement value of 300 Pa is 630 Å, and 580 Å is extracted as the data of the minus side thereof as shown in No. 2 of FIG. 9.

From the previously acquired data shown in FIG. 9, the predetermined pressure value p1 becomes 300 Pa, and the film thickness c1 becomes 630 Å. Also, the predetermined pressure value pm becomes 200 Pa, and the film thickness tc becomes 580 Å. That is, the pressure correction amount acquired from the following equation is required in order to change the film thickness tc by 50 Å from 580 Å to 630 Å:

300 Pa(p1)−200 Pa(pm)=+100 Pa.

A case where a current pressure measurement value is set to 300 Pa and a film thickness acquired from the measurement results is set to 600 Å will be illustrated as one example.

In this case, first, a film thickness corresponding to a currently used predetermined pressure value is used as a search key, and the closest film thickness from the plus and minus sides of the stored data is selected from a previously measured value shown in FIG. 9 using the search key, and calculation is then performed using the selected data.

Thus, the pressure correction amount is calculated as follows:

Pressure Correction Amount per +1 Å=+100 Pa/50 Å=+2 Pa/Å.

That is, since the correction is performed by (c1−a1)=+30 Å, the pressure correction amount is calculated as follows:

+30 Å*(+2 Pa/Å)=+60 Pa.

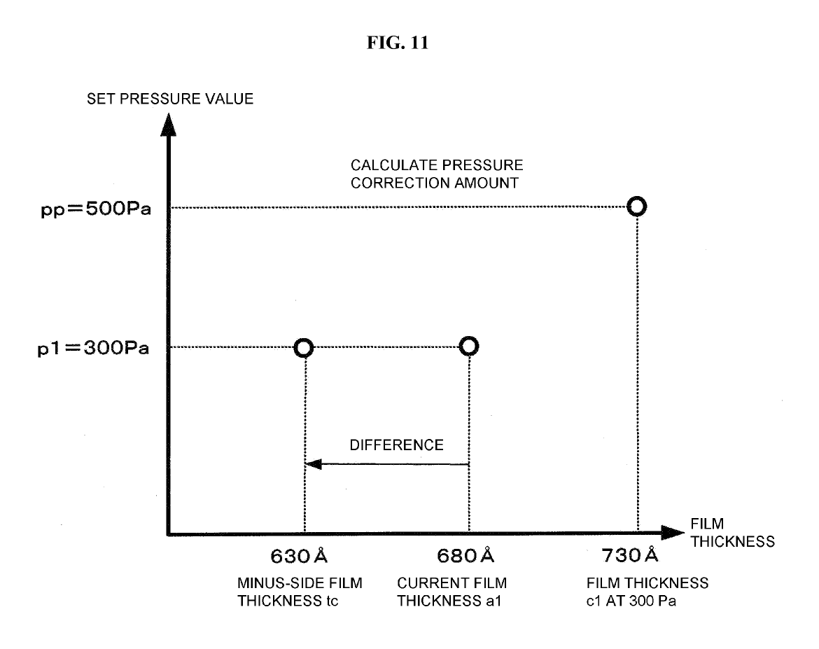

FIG. 11 is an explanation diagram illustrating an equation for calculation of the pressure correction amount px when of a1>c1.

First, a difference between a previously acquired film thickness c1 and a current film thickness a1 is calculated in the same manner as above a1<c1.

Next, a pressure correction amount for an increase of film thickness by +1 Å is calculated from the previously acquired data as (pp−p1)/(pc−c1) from relationships of “a current predetermined pressure value p1 and a film thickness c1 corresponding to p1” and “a detected plus-side pressure value pp and a film thickness pc corresponding to pp.” That is, the film thickness corresponding to 300 Pa is 630 Å, and 730 Å is detected as the data of the plus side thereof as shown in No. 4 of FIG. 9.

From the previously acquired data shown in FIG. 9, the predetermined pressure value p1 becomes 300 Pa, and the film thickness c1 becomes 630 Å. Also, the predetermined pressure value pp becomes 500 Pa, and the film thickness pc becomes 730 Å. That is, the pressure correction amount acquired from the following equation is required in order to change the film thickness by −100 Å from 730 Å to 630 Å:

300 Pa(p1)−500 Pa(pp)=−200 Pa

For example, a case where a current pressure measurement value is set to 300 Pa and a film thickness acquired from the measurement results is set to 680 Å will be illustrated as one example.

In this case, first, a film thickness corresponding to a currently used predetermined pressure value is used as a search key, the closest film thickness from the plus and minus sides of the stored data is selected from a previously measured value shown in FIG. 9 using the search key, and calculation is then performed using the selected data.

Thus, the pressure correction amount is calculated as follows:

Pressure Correction Amount per +1 Å=−200 Pa/−100 Å=+2 Pa/Å.

That is, since the correction is performed by (c1-a1)=−50 Å, the pressure correction amount is calculated as follows:

−50 Å*(+2 Pa/Å)=−100 Pa.

The pressure correction amount px when one of the current film thickness a1 of the wafer 54 and the film thickness c1 corresponding to the current predetermined pressure value p1 is higher than the other has been explained above, but the correction is unnecessary when a1 and c1 are equal to each other.

Furthermore, in the above-described calculation of the pressure correction value, the reason for calculating the pressure correction amount for an increase of the film thickness by 1 Å using the relationships of a detected plus-side or minus-side pressure value and a film thickness corresponding to the detected plus-side or minus-side pressure value, and a current predetermined pressure value p1 and a film thickness c1 corresponding to the current predetermined pressure value p1 is that the pressure correction amount is considered to vary according to the film thickness.

For example, the pressure correction amount used to change the film thickness by +50 Å from 580 Å to 630 Å is not necessarily equal to the pressure correction amount used to change the film thickness by +50 Å from 630 Å to 680 Å since the heat amount which the wafer 54 receives varies due to variations in radiant heat from the wire of the heater 58, heat transfer from the edge part of the wafer 54 to the reaction tube 14, and heat transfer between the central part and the edge part of the wafer 54.

Therefore, in the semiconductor manufacturing apparatus 10 according to this embodiment, in order to calculate a pressure correction amount using variations in closer film thickness, a pressure correction amount is calculated using a minus-side film thickness and a predetermined pressure value when a current film thickness is smaller than a film thickness corresponding to a current predetermined pressure value, and a pressure correction amount is calculated using a plus-side film thickness and a predetermined pressure value when a current film thickness is greater than a film thickness corresponding to a current predetermined pressure value.

In the present invention, the pressure correction amount may be calculated using the boat ceiling part temperature correction value measured in the boat ceiling thermocouple, and may also be calculated using a cap part temperature correction value or a wafer central part temperature correction value which may be measured in a cap TC or a wafer central thermocouple.

For example, a pressure correction value may also be calculated from an average temperature deviation of both the boat ceiling part temperature correction value measured in the boat ceiling thermocouple and the cap part temperature correction value measured in the cap TC, or an average temperature deviation of all three of the wafer central part temperature correction value measured in the wafer central thermocouple and both of the boat ceiling part temperature correction values.

Next, a third embodiment of the present invention will be described.

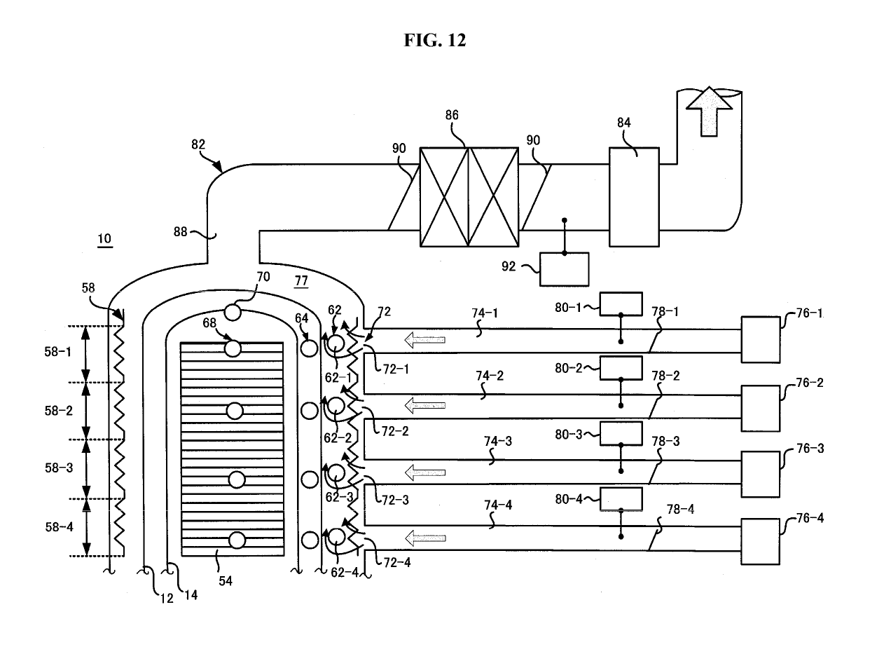

According to the above-described embodiment, a plurality of inhalation tubes 74-1 through 74-4 are connected to one cooling gas inhalation device 76, and the inhalation tubes 74-1 through 74-4 are connected to the cooling gas channel 77 via the inhalation ports 72-1 through 72-4, respectively, as shown in FIG. 3. According to the third embodiment of the present invention, a plurality of cooling gas inhalation devices 76-1 through 76-4 are provided, as shown in FIG. 12. Here, the plurality of inhalation tubes 74-1 through 74-4 are connected to the plurality of cooling gas inhalation devices 76-1 through 76-4, respectively, and the inhalation tubes 74-1 through 74-4 are connected to the cooling gas channel 77 via the inhalation ports 72-1 through 72-4, respectively.

That is, outputs of the cooling gas inhalation devices 76-1 through 76-4 in every cooling gas channel, for example, frequencies of blowers, may be controlled by installing a plurality of cooling gas inhalation devices in every inhalation tube, which makes it possible to control a pressure value of a cooling gas supply side more elaborately and widely.

Next, a fourth embodiment of the present invention will be described.

In the above-described embodiments, the pressure correction amount px is calculated using the temperature correction value of the boat ceiling part, whereas in this fourth embodiment, a DEPO processing time correction amount tx is calculated using a film thickness of the wafer 54 on which a thin film is formed in advance. Hereinafter, the fourth embodiment will be described in detail. In the description, data such as a measured film thickness is used for the wafer 54 on which a thin film is formed in advance under certain conditions as shown in FIG. 9.

When a current film thickness of the wafer 54 is referred to as “a1,” a current DEPO processing time is referred to as “t1,” a film thickness corresponding to the current DEPO processing time t1 is referred to as “c1,” a searched plus-side DEPO processing time is referred to as “tp,” a plus-side film thickness in a plurality of previously acquired data is referred to as “pc,” a minus-side DEPO processing time in a plurality of previously acquired data is referred to as “tm,” and a minus-side film thickness is referred to as “tc,” a DEPO processing time tx is calculated from the following Equations 23 and 24, depending on sizes of the current film thickness a1 and the film thickness c1 corresponding to the current DEPO processing time t1.

That is, the DEPO processing time tx is calculated as follows:

If a1<c1,

tx=(c1−a1)*{(t1−tm)/(c1−tc)} (Equation 23)

If a1>c1,

tx=(c1−a1)*{(tp−t1)/(pc−c1)} (Equation 24).

Hereinafter, the cases in which a1<c1 and a1>c1 will be described in further detail as one example.

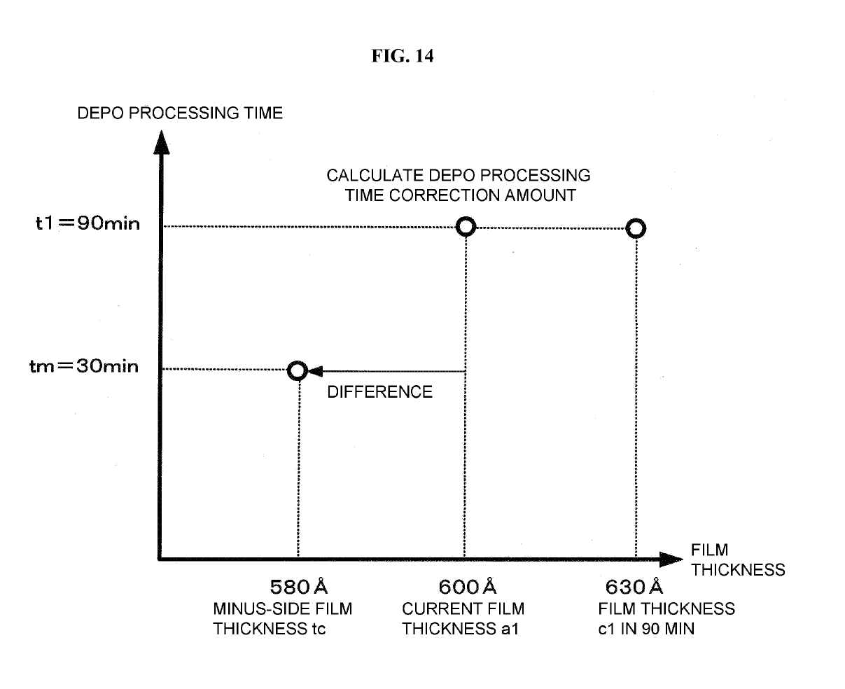

FIG. 14 is an explanation diagram illustrating calculation of the DEPO processing time correction amount tx when a1<c1.

First, a difference between a previously acquired film thickness c1 and a current film thickness a1 is calculated as c1−a1.

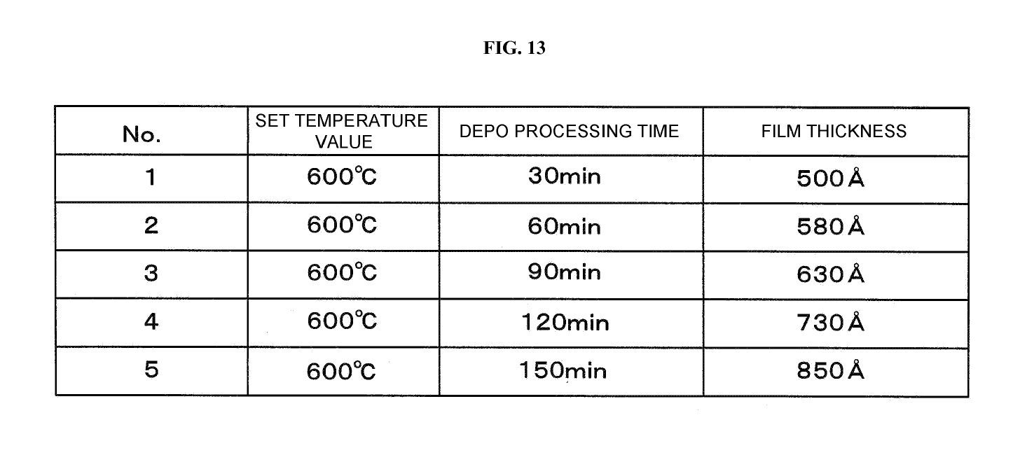

Next, a DEPO processing time correction amount for a film thickness of −1 Å is calculated from the previously acquired data as (t1−tm)/(c1−tc) from relationships of “a current DEPO processing time t1 and a film thickness c1 corresponding to t1” and “a detected minus-side DEPO processing time tm and a film thickness tc corresponding to tm.” That is, the film thickness corresponding to the DEPO processing time of 90 minutes is 630 Å, and 580 Å is extracted as the data of the minus side thereof as shown in No. 2 of FIG. 13.

From the previously acquired data shown in FIG. 13, the DEPO processing time t1 becomes 90 minutes, and the film thickness c1 becomes 630 Å. Also, the DEPO processing time t1 becomes 60 minutes, and the film thickness tc becomes 580 Å. That is, the DEPO processing time correction amount acquired from the following equation is required in order to change the film thickness tc by 50 Å from 580 Å to 630 Å:

90 min(t1)−60 min(tm)=+30 min.

A case where a current DEPO processing time is set to 90 minutes and a film thickness acquired from the measurement results is set to 600 Å will be illustrated as one example.

In this case, first, a film thickness corresponding to a currently used DEPO processing time is used as a search key, and the closest film thickness from the plus and minus sides of the stored data is selected from a previously measured value shown in FIG. 13 using the search key, and calculation is then performed using the selected data.

Thus, the DEPO processing time correction amount is calculated as follows:

DEPO Processing Time Correction Amount per +1 Å=+30 min/50 Å=+0.6 min/Å

That is, since the correction is performed by (c1−a1)=+30 Å, the DEPO processing time correction amount is calculated as follows:

+30 Å*(+0.6 min/Å)=+18 min.

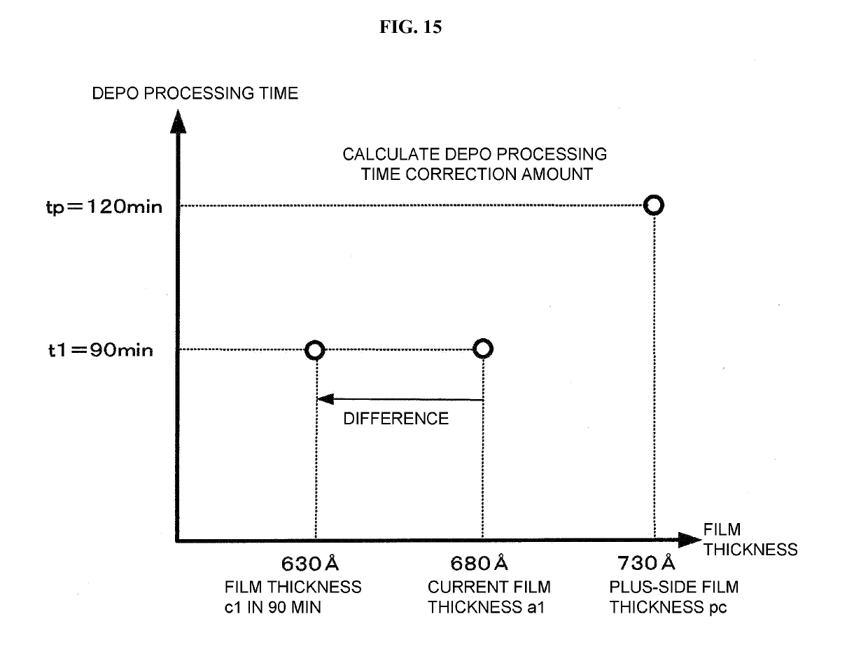

FIG. 15 is an explanation diagram illustrating calculation of the DEPO processing time correction amount tx when a1>c1.

First, a difference between a previously acquired film thickness c1 and a current film thickness a1 is calculated in the same manner as above a1<c1.

Next, a DEPO processing time correction amount for an increase of the film thickness by +1 Å is calculated from the previously acquired data as (tp−t1)/(pc−c1) from relationships of “a current DEPO processing time t1 and a film thickness c1 corresponding to t1” and “a detected plus-side DEPO processing time tp and a film thickness pc corresponding to tp.” That is, the film thickness corresponding to 90 minutes is 630 Å, and 730 Å is extracted as the data of the plus side thereof as shown in No. 4 of FIG. 13.

From the previously acquired data shown in FIG. 13, the DEPO processing time t1 becomes 90 minutes, and the film thickness c1 becomes 630 Å. Also, the DEPO processing time tp becomes 120 minutes, and the film thickness pc becomes 730 Å. That is, the DEPO processing time correction amount acquired from the following equation is required in order to change the film thickness tc by −100 Å from 730 Å to 630 Å:

90 min(t1)−120 min(tp)=−30 min.

For example, a case where a current DEPO processing time is set to 90 minutes and a film thickness acquired from the measurement results is set to 680 Å will be illustrated as one example. In this case, first, a film thickness corresponding to a current DEPO processing time is used as a search key, and the closest film thickness from the plus and minus sides of the stored data is selected from a previously measured value shown in FIG. 13 using the search key, and calculation is then performed using the selected data.

Thus, the DEPO processing time correction amount is calculated as follows:

DEPO Processing Time Correction Amount per +1 Å=−30 min/−100 Å=+0.3 min/Å.

That is, since the correction is performed by (c1−a1)=−50 Å, the DEPO processing time correction amount is calculated as follows:

50 Å*(+0.3 min/Å)=−15 min.

The DEPO processing time correction amount tx when one of the current film thickness a1 of the wafer 54 and the film thickness c1 corresponding to the current DEPO processing time t1 is higher than the other has been explained above, but the correction is unnecessary when a1 and c1 are equal to each other.

Furthermore, in the above-described calculation of the DEPO processing time correction value, the reason for calculating the DEPO processing time correction amount for an increase of the film thickness by 1 Å using the relationships of a detected plus-side or minus-side DEPO processing time and a film thickness corresponding to the detected plus-side or minus-side DEPO processing time, and a current DEPO processing time t1 and a film thickness c1 corresponding to the current DEPO processing time t1 is that a DEPO rate, that is, a cumulative amount of films, is considered to vary according to the film thickness.

For example, the DEPO processing time correction amount used to change the film thickness by +50 Å from 580 Å to 630 Å is not necessarily equal to the DEPO processing time correction amount used to change the film thickness by +50 Å from 630 Å to 680 Å since the heat amount which the wafer 54 receives varies due to variations in radiant heat from the wire of the heater 58, heat transfer from the edge part of the wafer 54 to the reaction tube 14, and heat transfer between the central part and the edge part of the wafer 54.

Therefore, in the semiconductor manufacturing apparatus 10 according to this embodiment, in order to calculate a DEPO processing time correction amount using variations in closer film thickness, a DEPO processing time correction amount is calculated using a minus-side film thickness and a DEPO processing time when a current film thickness is smaller than a film thickness corresponding to a current DEPO processing time, and a DEPO processing time correction amount is calculated using a plus-side film thickness and a DEPO processing time when a current film thickness is greater than a film thickness corresponding to a current DEPO processing time.

Next, a fifth embodiment of the present invention will be described.

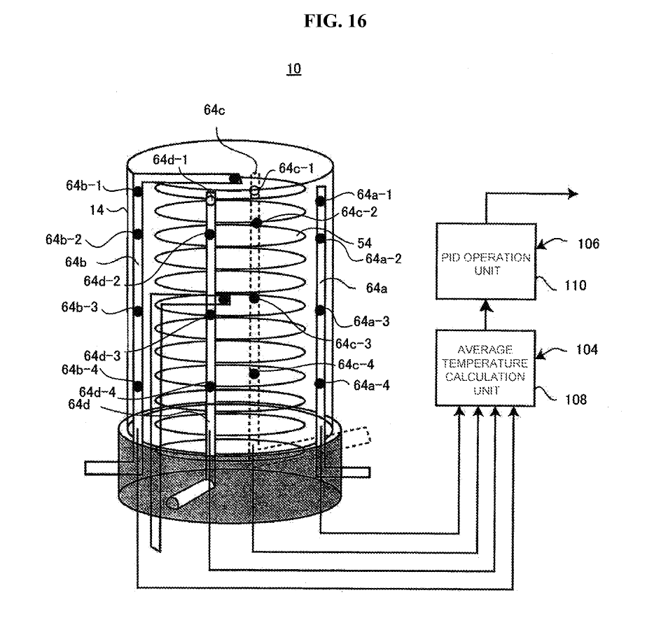

FIG. 16 illustrates a configuration of a semiconductor manufacturing apparatus 10 according to a fifth embodiment of the present invention. In the above-described embodiments, the semiconductor manufacturing apparatus 10 includes, for example, one second thermocouple 64 extending between the uniform heat tube 12 and the reaction tube 14 along a stacking direction of the wafers 54. In this case, the one second thermocouple 64 is horizontally divided from an upper portion to a lower portion thereof, and a control operation is performed using thermocouples 64-1 through 64-4 disposed in the divided regions. Therefore, in the semiconductor manufacturing apparatus 10 according to this fifth embodiment, a plurality of thermocouples 64a, 64b, 64c and 64d extending along a stacking direction of the wafers 54 are disposed in a circumferential direction of the wafer 54, and disposed between the uniform heat tube 12 and the reaction tube 14. Each of the plurality of thermocouples 64a through 64d is horizontally divided from an upper portion to a lower portion thereof, and a value obtained by averaging temperatures detected from thermocouples 64a-1 through 64d-1, 64a-2 through 64d-2, 64a-3 through 64d-3, and 64a-4 through 64d-4 disposed at the same height is used for a control operation.

More specifically, as shown in FIG. 16, outputs from a second thermocouple 64a-1, a second thermocouple 64b-1, a second thermocouple 64c-1 and a second thermocouple 64d-1 are, for example, input into an average temperature calculation unit 108 included in the control unit 104, an average value of these outputs is calculated at the average temperature calculation unit 108, the average value is output to the PID operation unit 110 in the temperature control unit 106, and an output of the PID operation unit 110 is, for example, used for a control operation such as control of the heater 58.

That is, the temperatures are averaged by temperature detection points having the same height detected by the plurality of second thermocouples 64a through 64d, and a circumferential part of the wafer 54 is controlled by performing PID control so that a deviation in previously set temperature value can become 0.

As described above, a temperature around an edge part (a circumferential part) of the wafer 54 can be estimated when the boat 52 rotates by averaging the temperatures by means of the temperature detection points having the same height detected by the plurality of second thermocouples 64a through 64d disposed in a circumferential direction of the wafer 54 and controlling the temperatures, which makes it possible to control the edge part of the wafer 54 to a more adequate value.

That is, in the semiconductor manufacturing apparatus 10 according to the fifth embodiment, a plurality of temperature detection units are provided in the vicinity of surroundings of a substrate, a value obtained by averaging detected temperatures is used for a control operation, and thus a difference in temperature in a circumferential direction of the substrate is expected to be reduced and reproducibility of film thickness is expected to be improved.

Also, in the semiconductor manufacturing apparatus 10 according to the fifth embodiment, a case where the plurality of second thermocouples 64 are installed has been explained, but the present invention is not limited thereto. Therefore, the present invention may be applied to other thermocouples such as the first thermocouple 62.

Also, in the semiconductor manufacturing apparatus 10 according to each embodiment, configurations other than the configurations particularly described above are identical to those of the above-described first embodiment of the present invention, and thus the description of the configurations is omitted for clarity.

According to the present invention, the uniformity in film thickness between wafers or the reproducibility of film quality can be improved, particularly when a quenching mechanism is used during film formation, by detecting variations in cooling performance in a vertical direction of a reaction furnace and controlling a pressure value of a cooling gas supply side according to the variations in cooling performance.

What is claimed is:

1. A heat treatment apparatus comprising:
a processing chamber configured to process a substrate;
a heating device configured to heat the substrate from a circumferential side of the substrate accommodated in the processing chamber;
a cooling gas channel installed between the heating device and the processing chamber;
a cooling device configured to flow a cooling gas into the cooling gas channel;
a plurality of cooling gas inhalation passages installed between the cooling device and the cooling gas channel, each of the plurality of cooling gas inhalation passages communicating with the cooling gas channel in a region defined by horizontally dividing the heating device;
a first pressure detector installed in each of the plurality of cooling gas inhalation passages; and
a control unit configured to control the cooling device based on a first pressure value detected by the first pressure detector.

2. The heat treatment apparatus according to claim 1, further comprising a cooling gas exhaust passage configured to communicate with the cooling gas channel at a downstream side of the cooling gas channel,
wherein a second pressure detector is installed in the cooling gas exhaust passage, and
the control unit controls at least one of the heating device and the cooling device based on a second pressure value detected by the second pressure detector.

3. The heat treatment apparatus according to one of claims 1 and 2, wherein the control unit performs: acquiring a measurement value of a first detection unit configured to detect a state of a peripheral part of the substrate and a measurement value of a second detection unit configured to detect a state of a central part of the substrate; calculating a first deviation between the measurement value of the first detection unit and the measurement value of the second detection unit; comparing the first deviation with a second deviation between a previously stored measurement value of the first detection unit and a previously stored measurement value of the second detection unit; calculating a pressure correction value of a predetermined pressure value in the cooling gas channel based on the first deviation when the second deviation and the first deviation are different from each other; and correcting the predetermined pressure value by means of the pressure correction value.

4. A method of processing a substrate, comprising:
heating a substrate from a circumferential side of the substrate accommodated in a processing chamber configured to process the substrate using a heating device;
flowing a cooling gas from a plurality of cooling gas inhalation passages to a cooling gas channel installed between the heating device and the processing chamber using a cooling device, each of the plurality of cooling gas inhalation passages communicating with the cooling gas channel in a region defined by horizontally dividing the heating device;
detecting a pressure value in the plurality of cooling gas inhalation passages using a pressure detector; and
controlling the cooling device by a control unit based on the pressure value detected by the pressure detector.

5. The method according to claim 4, further comprising:
acquiring by the control unit a measurement value of a first detection unit configured to detect a state of a peripheral part of the substrate and a measurement value of a second detection unit configured to detect a state of a central part of the substrate, calculating a first deviation between the measurement value of the first detection unit and the measurement value of the second detection unit, comparing the first deviation with a second deviation between a previously stored measurement value of the first detection unit and a previously stored measurement value of the second detection unit, calculating a pressure correction value of a predetermined pressure value in the cooling gas channel based on the first deviation when the second deviation and the first deviation are different from each other, and correcting the predetermined pressure value by means of the pressure correction value; and
flowing the cooling gas into the cooling gas channel using the cooling device while heating the processing chamber using the heating device, controlling the heating device and the cooling device based on a corrected predetermined pressure value using the control unit, and processing the substrate.
